(19) United States
(12) Patent Application Publication
(10) Pub. No.: US 2010/0078647 A1
(43) Pub. Date: Apr. 1, 2010

(54) THIN FILM TRANSISTOR SUBSTRATE AND ORGANIC LIGHT EMITTING DISPLAY HAVING THE SAME

(76) Inventor: Ji-Hye Eom, Suwon-si (KR)

Correspondence Address: Innovation Counsel LLP, 21771 Stevens Creek Blvd, Ste. 200A, Cupertino, CA, 95014, US

(21) Appl. No.: 12/569,816

(22) Filed: Sep. 29, 2009

(30) Foreign Application Priority Data
Sep. 30, 2008 (KR) 10-2008-0095938

(51) Int. Cl. H01L 29/786; H01L 51/52

(52) U.S. Cl. 257/72; 257/66; 257/E29.273; 257/E51.018

(57) ABSTRACT

In an organic light emitting display, a switching transistor includes an active pattern having a crystal structure grown at an angle of 0°±10° relative to a current flow direction, and a driving transistor includes an active pattern having a crystal structure grown at an angle of 90°±10° relative to a current flow direction. As a result, the driving transistor more precisely controls intensity of supply voltage applied to an organic light emitting layer.

### CROSS-REFERENCE TO RELATED APPLICATION

This application claims priority to Korean Patent Application No. 2008-95938 filed on Sep. 30, 2008, the entire contents of which are herein incorporated by reference in their entirety.

### BACKGROUND

1. Field of the Invention

The present invention relates to flat panel displays. More particularly, the present invention relates to a thin film transistor substrate including thin film transistors having electric characteristics different from each other, and an organic light emitting display having the thin film transistor substrate.

2. Description of the Related Art

Recently, organic light emitting displays (OLEDs) have been the subject of steadily increasing attention. In general, an OLED includes a top electrode, a bottom electrode, an organic light emitting layer interposed between the top and bottom electrodes to emit light, a switching thin film transistor to control data voltage, and a driving thin film transistor to apply current to a light emitting device by transferring the data voltage from the switching thin film transistor to a gate electrode.

Since the brightness of light generated from the organic light emitting layer is controlled by this current, which is in turn controlled by the driving thin film transistor, the current should preferably be precisely controlled by the driving thin film transistor in order to prevent brightness variation between pixels.

### SUMMARY

Therefore, an exemplary embodiment of the present invention provides a thin film transistor substrate having a thin film transistor capable of more precisely controlling current applied to an organic light emitting layer.

Another exemplary embodiment of the present invention also provides an organic light emitting display having a thin film transistor and an organic light emitting layer, which receives current controlled by the thin film transistor to emit light.

In an exemplary embodiment of the present invention, a thin film transistor substrate includes a substrate, a first thin film transistor provided on the substrate, and a second thin film transistor provided on the substrate and switched by the first thin film transistor. The first thin film transistor includes a first semiconductor pattern having a crystal structure grown at an angle of 0°±10° relative to a current flow direction in the first thin film transistor. The second thin film transistor includes a second semiconductor pattern having a crystal structure grown at an angle of 90°±10° relative to a current flow direction in the second thin film transistor.

In another exemplary embodiment of the present invention, an organic light emitting display includes a substrate having a plurality of pixel areas, each pixel area having a first electrode provided on the substrate, an organic light emitting layer provided on the first electrode, a second electrode provided on the organic light emitting layer, a first thin film transistor provided on the substrate, and a second thin film transistor switched by the first thin film transistor. For each pixel area, the first thin film transistor includes a first semiconductor pattern having a crystal structure grown at an angle of 0°±10° relative to a current flow direction in the first thin film transistor. In addition, the second thin film transistor is electrically connected to the first thin film transistor and the first electrode and includes a second semiconductor pattern having a crystal structure grown at an angle of 90°±10° relative to a current flow direction in the second thin film transistor.

According to the above, the switching thin film transistor is prepared as a horizontal thin film transistor and the driving thin film transistor is prepared as a vertical thin film transistor, so that current supplied to the organic light emitting layer through the vertical thin film transistor is more uniformly controlled, thereby improving the characteristics of light generated from the organic light emitting layer.

### BRIEF DESCRIPTION OF THE DRAWINGS

The above and other advantages of the present invention will become readily apparent by reference to the following detailed description when considered in conjunction with the accompanying drawings wherein:

FIG. 1 is a plan view showing an organic light emitting display according to an exemplary embodiment of the present invention;

FIG. 2A is a sectional view taken along line I-I′ shown in FIG. 1;

FIG. 2B is a sectional view taken along line II-II′ shown in FIG. 1;

FIG. 3A is an enlarged view showing a first area illustrated in FIG. 1;

FIG. 3B is an enlarged view showing a second area illustrated in FIG. 1;

FIGS. 4A and 4B are enlarged views showing silicon crystal structures of semiconductor patterns of organic light emitting displays according to another exemplary embodiment of the present invention; and

FIGS. 5A and 5B are graphs showing electric characteristics of a thin film transistor according to the relation between a current flow direction in a thin film transistor and a growth direction of silicon crystal.

### DESCRIPTION OF THE EMBODIMENTS

Hereinafter, embodiments of the present invention will be described in detail with reference to accompanying drawings. However, the scope of the present invention is not limited to such embodiments and the present invention may be realized in various forms. The embodiments to be described below are nothing but the ones provided to bring the disclosure of the present invention to perfection and assist those skilled in the art to completely understand the present invention. The present invention is defined only by the scope of the appended claims. In addition, the size of layers and regions shown in the drawings can be simplified or magnified for the purpose of clear explanation. Also, the same reference numerals are used to designate the same elements throughout the drawings.

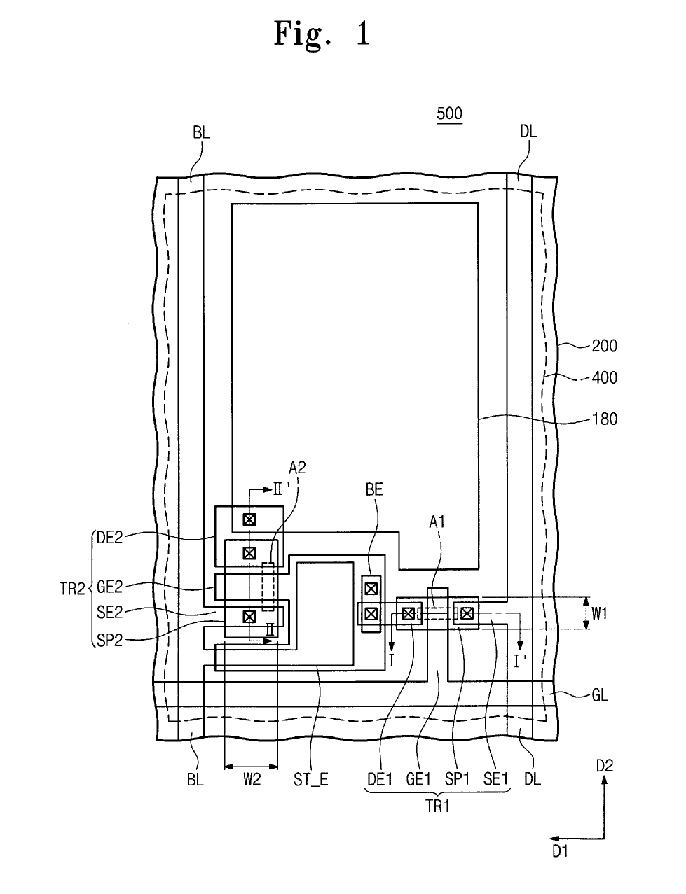

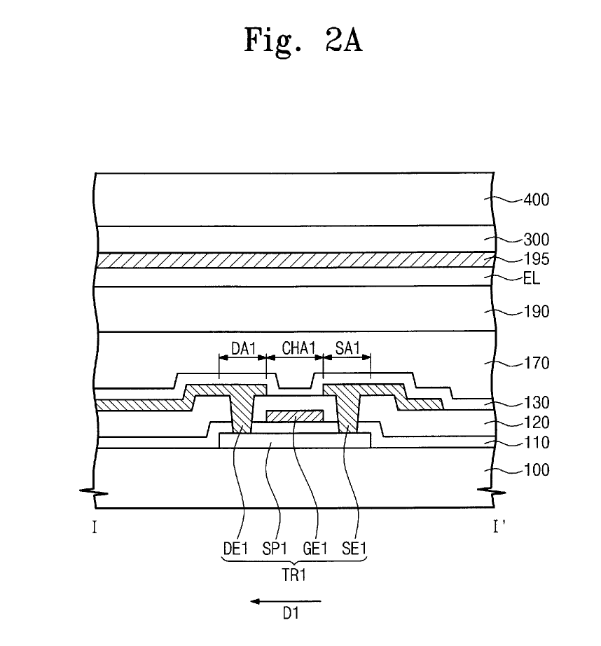

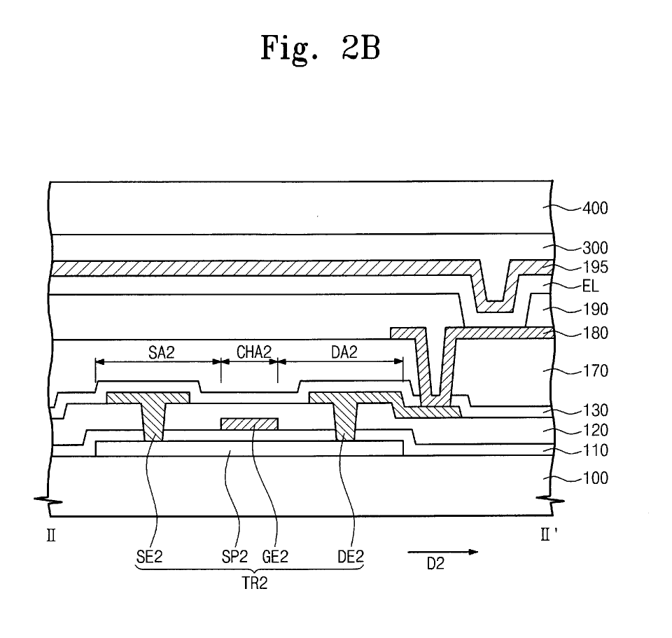

FIG. 1 is a plan view showing an organic light emitting display according to an exemplary embodiment of the present invention, and FIG. 2A is a sectional view taken along line I-I′ of FIG. 1.

Referring to FIGS. 1 and 2A, an organic light emitting display 500 includes a display substrate 200 and an opposite substrate 400 facing the display substrate 200. The display substrate 200 includes a plurality of pixel areas. Generally, pixels are provided in the pixel areas in one-to-one correspondence. The pixels also generally have the same structure, so only one pixel is shown in FIG. 1 for the purpose of simplicity.

The display substrate 200 includes a substrate 100, a gate line GL, a data line DL, a power supply line BL, a first thin film transistor TR1, a second thin film transistor TR2, a first electrode (see 180 in FIG. 2B), a second electrode (see 195 in FIG. 2B), an organic light emitting layer (see EL in FIG. 2B), a storage electrode ST_E, a first insulating layer 110, a second insulating layer 120, a third insulating layer 130, an overcoat layer 170, a bank pattern 190, and a protective layer 300.

The gate line GL is provided on the substrate 100 in a first direction D1 to transmit a gate signal. The data line DL and the power supply line BL, which are insulated from the gate line GL, are also provided on the substrate 100. Here, the data line DL and the power supply line BL both extend in a second direction D2 substantially perpendicular to the first direction D1. The date line DL transmits a data signal, and the power supply line BL transmits a supply voltage for powering the organic light emitting layer EL.

The first thin film transistor TR1 includes a first semiconductor pattern SP1, a first source electrode SE1, a first drain electrode DE1, and a first gate electrode GE1. The first thin film transistor TR1 is a top gate-type thin film transistor, and the first gate electrode GE1 is positioned higher than the first semiconductor pattern SP1.

The first semiconductor pattern SP1 is provided on the substrate 100. In the first thin film transistor TR1, the first semiconductor pattern SP1 functions as an active layer. When viewed in a plan view, the first semiconductor pattern SP1 extends in the first direction D1, and has a first width W1.

The first semiconductor pattern SP1 is divided into a first channel area CHA1, a first source area SA1, and a first drain area DA 1. The first source area SA1 and the first drain area DA 1 include doped ions.

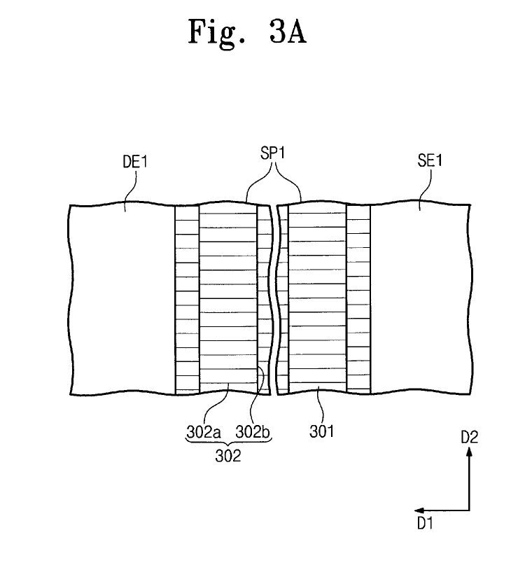

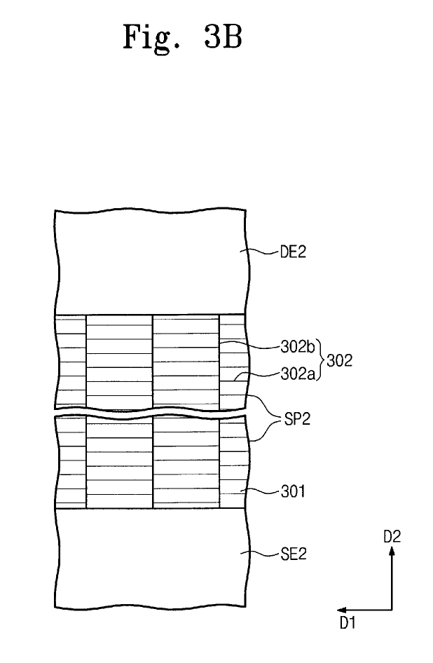

Meanwhile, the first semiconductor pattern SP1 includes silicon crystals having an anisotropic crystal structure. The crystal structure of the silicon crystals will be described in more detail with reference to FIG. 3A.

FIG. 3A is an enlarged view showing a first area A1 illustrated in FIG. 1. Referring to FIG. 3A, the first semiconductor pattern SP1 includes a plurality of silicon crystals 301. The silicon crystals 301 have an anisotropic crystal structure. In more detail, each of the silicon crystals 301 extends generally parallel to the first direction D1. This is because the silicon crystals 301 are grown in a direction generally parallel to the first direction D1.

In order to allow the silicon crystals 301 to be grown in parallel to the first direction D1, the silicon crystals 301 are preferably crystallized by using a sequential lateral solidification (SLS) process. The sequential lateral solidification process takes advantage of the fact that silicon crystals grow in a direction perpendicular to the boundary area between liquid phase silicon and solid phase silicon.

In a typical sequential lateral solidification process, amorphous silicon is crystallized by using a laser beam. The irradiation range of the laser beam is adjusted by using a mask, so that the silicon crystal grows in a lateral direction by a certain length. For example, although not shown in FIG. 3A in detail, if a mask formed with a slit that is open in parallel to the second direction D2 is provided on the first semiconductor pattern SP1, and the laser beam is irradiated into the first semiconductor pattern SP1 through the mask, the laser beam, which has passed through the slit, partially melts the first semiconductor pattern SP1. The laser liquefies silicon exposed by the open slit in the mask, producing a solid-liquid silicon boundary along the edge of the slit, i.e., a boundary that runs along direction D2. As a result, the silicon crystals grow in the first direction D1, perpendicular to direction D2.

This crystal growth produces grain boundaries 302, formed at the boundary between the silicon crystals 301. Each grain boundary 302 can be thought of as including a primary crystal grain boundary 302b and a secondary crystal grain boundary 302a, where the primary crystal grain boundary 302b is generally formed in a direction perpendicular to the growth direction of the silicon crystals 301, and the secondary crystal grain boundary 302a is generally formed in a direction parallel to the growth direction of the silicon crystals 301.

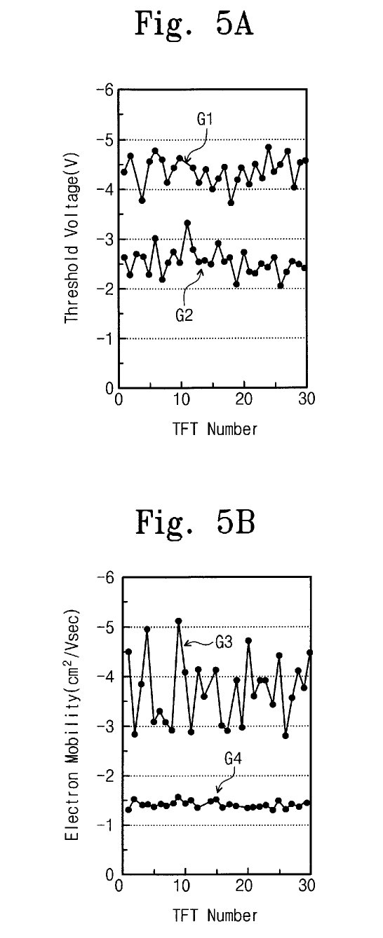

The electrical characteristics of the first thin film transistor TR1 depend on current flow direction in the well/channel, i.e. the first semiconductor pattern SP1, and thus depend on an angle defined by the growth direction of the silicon crystals 301. This will be described in more detail with reference to FIGS. 5A and 5B.

Meanwhile, a first insulating layer 110 is provided on the first semiconductor pattern SP1 and a first gate electrode GE1 is provided on the first insulating layer 110, such that the first gate electrode GE1 overlaps the first semiconductor pattern SP1. The first gate electrode GE1 branches from the gate line GL.

A second insulating layer 120 is provided to cover the first gate electrode GE1. A first source electrode SE1 and first drain electrode DE1 are then provided on the second insulating layer 120, where the first source electrode SE1 branches from the data line DL, and the first drain electrode DE1 is spaced apart from the first source electrode SE1. The first and second insulating layers 110 and 120 are partially removed, such that the first source electrode SE1 makes contact with the first semiconductor pattern SP1 on the first source area SA1 and the first drain electrode DE1 makes contact with the first semiconductor pattern SP1 on the first drain area DA1.

When the first thin film transistor TR1 is turned on by a gate signal transmitted from the first gate electrode GE1, the data signal transmitted through the data line DL is applied to the first drain electrode DE1 by sequentially passing through the first source electrode SE1 and the first semiconductor pattern SP1. When the first thin film transistor TR1 is turned on, the transmission direction of the data signal in the first semiconductor pattern SP1 is parallel to the first direction D1, due to the orientation of the silicon crystals 301.

Meanwhile, when viewed in a plan view, the storage electrode ST_E branches from the power supply line BL and overlaps a second gate electrode GE2, thereby forming a storage capacitor together with the second gate electrode GE2.

A third insulating layer 130 is provided on the first source electrode SE1 and the first drain electrode DE1 to cover the first source electrode SE1 and the first drain electrode DE1. An overcoat layer 170 is then provided on the third insulating layer 130. The overcoat layer 170 is then covered by a bank pattern 190, which is in turn covered by an organic light emitting layer EL and a second electrode 195. The second electrode 195 is covered by protective layer 300. The protective layer 300 is provided over substantially the whole area of the second electrode 195, to protect components formed on the substrate 100, including the organic light emitting layer EL. If the protective layer 300 is sufficiently thick, an interval between the display substrate 200 and the opposite substrate 400 can be maintained. The overcoat layer 170, the bank pattern 190, the second electrode 195, and the organic light emitting layer EL will be described in more detail with reference to FIG. 2B, together with the first electrode (see 180 in FIG. 2B).

FIG. 2B is a sectional view taken along line II-II′ shown in FIG. 1.

Referring to FIG. 1 and FIG. 2B, a second thin film transistor TR2 is provided on the substrate 100. The second thin film transistor TR2 includes a second semiconductor pattern SP2, a second gate electrode GE2, a second source electrode SE2, and a second drain electrode DE2. The second thin film transistor TR2 is a top gate-type thin film transistor and the second gate electrode GE2 is positioned higher than the second semiconductor pattern SP2.

The second semiconductor pattern SP2 is provided on the substrate 100. In the second thin film transistor TR2, the second semiconductor pattern SP2 functions as an active layer. The second semiconductor pattern SP2 is divided into a second channel area CHA2, a second source area SA2 doped with ions, and a second drain area DA2. When viewed in a plan view, the second semiconductor pattern SP2 extends in the second direction D2 and has a second width W2 larger than the first width W1. This is because the growth direction of the silicon crystal of the second semiconductor pattern SP2 is perpendicular to the current flow direction in the second semiconductor pattern SP2, so that an amount of current flowing through the second semiconductor pattern SP2 is less than an amount of current flowing through the first semiconductor pattern SP1 in the same period of time. This will be described in more detail with reference to FIG. 3B.

FIG. 3B is an enlarged view showing a second area A2 illustrated in FIG. 1.

In FIG. 3B, similar to the first semiconductor pattern SP1, the second semiconductor pattern SP2 includes silicon crystals 301 having an anisotropic crystal structure. As described above with reference to FIG. 3A, the silicon crystals 301 have a crystal structure, which is grown in a direction parallel to the first direction D1.

The current flow direction in the second semiconductor pattern SP2 is parallel to the second direction D2 perpendicular to the first direction D1. That is, the current flow direction in the first semiconductor pattern (see SP1 in FIG. 3A) is parallel to the growth direction of the silicon crystals 301. In contrast, the current flow direction in the second semiconductor pattern SP2 is substantially perpendicular to the growth direction of the silicon crystals 301. Therefore, the electrical characteristics of the second thin film transistor (see TR2 of FIG. 1), which has second semiconductor pattern SP2 serving as an active layer, is different from the electrical characteristics of the first thin film transistor (see TR1 of FIG. 1), which has first semiconductor pattern SP1 serving as an active layer. This will be described in more detail with reference to FIGS. 5A and 5B.

Referring again to FIGS. 1 and 2B, the second semiconductor pattern SP2 has second gate electrode GE2 formed over it, with first insulating layer 110 provided inbetween. The second gate electrode GE2 is electrically connected to the first drain electrode DE1 by a connection electrode BE. Accordingly, when the first thin film transistor TR1 is turned on, the data signal is transmitted to the second gate electrode GE2 to turn on the second thin film transistor TR2.

The second gate electrode GE2 is proximate to a second source electrode SE2 branching from the power supply line BL, as well as a second drain electrode DE2 spaced apart from the second source electrode SE2. The second source electrode SE2 makes contact with the second semiconductor pattern SP2 on the second source area SA2, and the second drain electrode DE2 makes contact with the second semiconductor pattern SP2 on the second drain area DA2.

Meanwhile, when the second thin film transistor TR2 is turned on, the supply voltage from power supply line BL is applied to the second drain electrode DE2 via the second semiconductor pattern SP2. In the second semiconductor pattern SP2, the supply voltage is transmitted in a direction parallel to the second direction D2.

The overcoat layer 170 is provided on the first and second thin film transistors TR1 and TR2. The overcoat layer 170 has a flat top surface, so that the first electrode 180 can be easily formed on the overcoat layer 170.

The first electrode 180 is electrically connected to the second drain electrode DE2. Accordingly, when the second thin film transistor TR2 is turned on, the current is applied to the first electrode 180 through the second drain electrode DE2.

The bank pattern 190 is provided on the overcoat layer 170. The bank pattern 190 is partially removed, to define an area where the organic light emitting layer EL makes contact with the first electrode 180. The second electrode 195 overlies the organic light emitting layer EL.

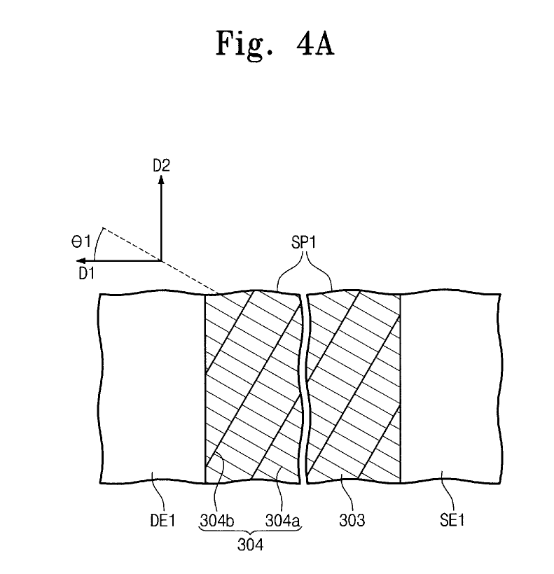

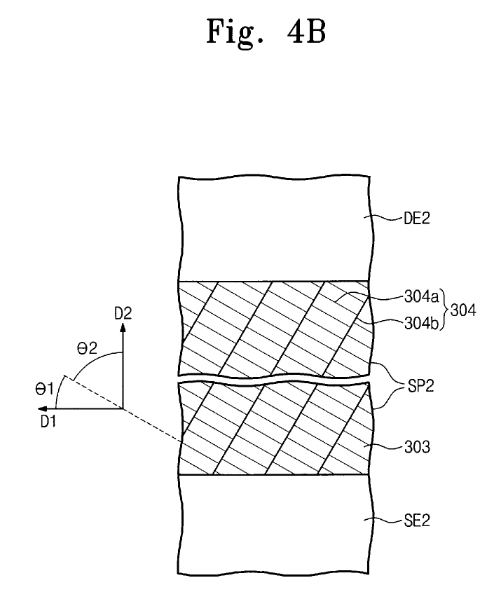

FIGS. 4A and 4B are enlarged views showing silicon crystal structures of semiconductor patterns of OLEDs according to another exemplary embodiment of the present invention. Referring to FIG. 4A, the first semiconductor pattern SP1 includes silicon crystals 303. Grain boundaries 304, including primary crystal grain boundaries 304b and secondary crystal grain boundaries 304a, are formed at the boundaries between the silicon crystals 303. The current flow direction in the first semiconductor pattern SP1 is parallel to the first direction D1, and the growth direction of the silicon crystals 301 is inclined by a first angle θ1 with respect to the current flow direction. In this embodiment, the first angle θ1 can be defined within a range of ±10° relative to the current flow direction in the first thin film transistor SP1.

Referring to FIG. 4B, the current flow direction in the second semiconductor pattern SP2 is parallel to the second direction D2, and the growth direction of the silicon crystals 303 is inclined by a second angle θ2 with respect to the second direction D2. In this embodiment, the second angle θ2 can be defined within a range of 90°±10°.

FIGS. 5A and 5B are graphs showing electrical characteristics of the thin film transistor according to the relation between a current flow direction in the thin film transistor and a growth direction of the silicon crystal.

Referring to FIG. 5A, one can define thin film transistors whose semiconductor patterns have crystal structures grown perpendicular to the current flow direction as “vertical type” thin film transistors. Using this definition, first graph G1 represents measurement values of threshold voltage as a function of particular numbered thin film transistors. One can also define thin film transistors whose semiconductor patterns have crystal structures grown parallel to the current flow direction as “horizontal type” thin film transistors. Using this definition, second graph G2 represents measurement values of threshold voltage as a function of TFT identity (i.e., the number assigned to a particular thin film transistor).

Referring to the first and second graphs G1 and G2, the average threshold voltage of the horizontal type thin film transistors is about −2.5 volts, and the average threshold voltage of the vertical type thin film transistors is about −4.5 volts. Therefore, the horizontal type thin film transistor can be turned on by a gate signal having intensity weaker than a gate signal applied to the vertical type thin film transistor. Accordingly, the horizontal type thin film transistor is often preferred for use as the first thin film transistor (see TR1 in FIG. 1.

Referring to FIG. 5B, a third graph G3 represents measurement values of electron mobility as a function of measured number of the horizontal type thin film transistors, and a fourth graph G4 represents measurement values of electron mobility as a function of measured number of the vertical type thin film transistors.

Referring to graphs G3 and G4, variation in the electron mobility of the horizontal type thin film transistors is larger than that of the vertical type thin film transistors. Thus, if the vertical type thin film transistor is used as the driving transistor instead of the horizontal type thin film transistor, the intensity of current applied to the device through the driving transistor can be more uniformly controlled. For example, as described in the embodiments of the present invention, if the vertical type thin film transistor is used as the driving transistor controlling current applied to the LE layer, the intensity of current applied to the LE layer of different pixels is more uniformly controlled, so that undesired differences in brightness between pixels can be reduced.

In addition, the variation in voltage required for the vertical type thin film transistor to increase its current by 10 times is greater than that for the horizontal type thin film transistor. As a result, if the vertical type thin film transistor is used as the thin film transistor controlling current applied to the LE layer, the difference in voltage between gray scales increases, so that the gray scale can be more easily expressed. Therefore, in the organic light emitting display (see 500 in FIG. 1) according to exemplary embodiments of the present invention, the vertical type thin film transistor is preferably used as the second thin film transistor (see TR2 in FIG. 2B) which drives the organic light emitting layer.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A thin film transistor substrate comprising:
a substrate;
a first thin film transistor provided on the substrate; and
a second thin film transistor provided on the substrate, electrically connected to the first thin film transistor, and switched by the first thin film transistor;
wherein the first thin film transistor comprises a first semiconductor pattern having a crystal structure grown at an angle of 0°±10° relative to a current flow direction in the first thin film transistor, and the second thin film transistor comprises a second semiconductor pattern having a crystal structure grown at an angle of 90°±10° relative to a current flow direction in the second thin film transistor.

2. The thin film transistor substrate of claim 1, wherein each of the first and second semiconductor patterns comprises polycrystalline silicon.

3. The thin film transistor substrate of claim 2, wherein a growth direction of the polycrystalline silicon in the first semiconductor pattern is substantially the same as a growth direction of the polycrystalline silicon in the second semiconductor pattern.

4. The thin film transistor substrate of claim 1, wherein the current flow direction in the first thin film transistor is substantially perpendicular to the current flow direction in the second thin film transistor.

5. The thin film transistor substrate of claim 1, further comprising:
a gate line provided on the substrate to supply a gate signal;
a data line insulated from the gate line and provided on the substrate to transmit a data signal; and
a power supply line provided on the substrate to transmit a supply voltage.

6. The thin film transistor substrate of claim 5, wherein the first thin film transistor comprises:
a first gate electrode branching from the gate line;
a first source electrode branching from the data line and provided on the first semiconductor pattern; and
a first drain electrode spaced apart from the first source electrode and provided on the first semiconductor pattern;
wherein the second thin film transistor comprises:
a second gate electrode electrically connected to the first drain electrode;
a second source electrode branching from the power supply line and provided on the first semiconductor pattern; and
a second drain electrode spaced apart from the second source electrode and provided on the second semiconductor pattern.

7. The thin film transistor substrate of claim 6, wherein the first source electrode and the first drain electrode are arranged substantially parallel to a growth direction of crystals of the first semiconductor pattern, and the second source electrode and the second drain electrode are arranged in a direction substantially perpendicular to a growth direction of crystals of the second semiconductor pattern.

8. The thin film transistor substrate of claim 1, wherein the first semiconductor pattern has a first width that extends generally perpendicular to the current flow direction in the first thin film transistor, the second semiconductor pattern has a second width that extends generally perpendicular to the current flow direction in the second thin film transistor, and the second width is larger than the first width.

9. An organic light emitting display comprising:
a substrate having a plurality of pixel areas, each pixel area having:
a first electrode provided on the substrate;
an organic light emitting layer provided on the first electrode;
a second electrode provided on the organic light emitting layer;
a first thin film transistor provided on the substrate; and
a second thin film transistor electrically connected to the first thin film transistor and the first electrode and switched by the first thin film transistor;
wherein, for each of the pixel areas, the first thin film transistor comprises a first semiconductor pattern having a crystal structure grown at an angle of 0°±10° relative to a current flow direction in the first thin film transistor, and the second thin film transistor comprises a second semiconductor pattern having a crystal structure grown at an angle of 90°±10° relative to a current flow direction in the second thin film transistor.

10. The organic light emitting display of claim 9, wherein each of the first and second semiconductor patterns comprises polycrystalline silicon.

11. The organic light emitting display of claim 10, wherein a growth direction of the polycrystalline silicon in the first semiconductor pattern is substantially the same as a growth direction of the polycrystalline silicon in the second semiconductor pattern.

12. The organic light emitting display of claim 9, wherein a channel direction of current in the first semiconductor pattern is substantially perpendicular to a channel direction of current in the second semiconductor pattern.

13. The organic light emitting display of claim 9, further comprising:
a gate line provided on the substrate to supply a gate signal;
a data line insulated from the gate line and provided on the substrate to transmit a data signal; and
a power supply line provided on the substrate to transmit a supply voltage.

14. The organic light emitting display of claim 13, wherein the first thin film transistor comprises:
a first gate electrode branching from the gate line;
a first source electrode branching from the data line and provided on the first semiconductor pattern; and
a first drain electrode spaced apart from the first source electrode and provided on the first semiconductor pattern;
wherein the second thin film transistor comprises:
a second gate electrode electrically connected to the first drain electrode;
a second source electrode branching from the power supply line and provided on the first semiconductor pattern; and
a second drain electrode spaced apart from the second source electrode, provided on the second semiconductor pattern, and electrically connected to the first electrode.

15. The organic light emitting display of claim 14, wherein the first source electrode and the first drain electrode are arranged substantially parallel to a growth direction of crystals of the first semiconductor pattern, and the second source electrode and the second drain electrode are arranged in a direction substantially perpendicular to a growth direction of crystals of the second semiconductor pattern.

16. The organic light emitting display of claim 9, wherein the first semiconductor pattern has a first width that extends generally perpendicular to the current flow direction in the first thin film transistor, the second semiconductor pattern has a second width that extends generally perpendicular to the current flow direction in the second thin film transistor, and the second width is larger than the first width.
